(19) United States
(12) Patent Application Publication
(10) Pub. No.: US 2026/0008133 A1
(43) Pub. Date: Jan. 8, 2026

(54) WAFER MANUFACTURING METHOD, LASER PROCESSING APPARATUS, AND WAFER MANUFACTURING APPARATUS

(71) Applicant: DISCO CORPORATION, Tokyo (JP)

(72) Inventor: Asahi Nomoto, Tokyo (JP)

(21) Appl. No.: 19/254,819

(22) Filed: Jun. 30, 2025

(30) Foreign Application Priority Data
Jul. 3, 2024 (JP) 2024-107420

(51) Int. Cl. B23K 26/53; B23K 26/08; B23K 101/40; B28D 5/00; H01L 21/02

(52) U.S. Cl. CPC B23K 26/53; B23K 26/083; B28D 5/0058; H01L 21/02013; H01L 21/02035; B23K 2101/40

(57) ABSTRACT

A method for manufacturing a wafer from an ingot includes: holding the ingot; applying a laser beam having a wavelength that transmits through the ingot from a front surface of the ingot and positioning a focal point of the laser beam at a position deeper than the front surface of the ingot to form a modified region, and relatively feeding the ingot and the focal point for processing to form a separation layer including a plurality of the modified regions inside the ingot; separating, from the ingot, a workpiece including the front surface of the ingot as the wafer, with the separation layer as a start point; and grinding a separation surface of the wafer to remove the modified region. In the applying, a depth of the focal point forming the modified region is changed to form the separation surface into a three-dimensional shape rather than a horizontal surface.

### CROSS-REFERENCE TO RELATED APPLICATIONS

This application is based on and claims priority under 35 USC 119 from Japanese Patent Application No. 2024-107420 filed on Jul. 3, 2024, the contents of which are incorporated herein by reference.

### TECHNICAL FIELD

The present disclosure relates to a wafer manufacturing method, a laser processing apparatus, and a wafer manufacturing apparatus for manufacturing a wafer from an ingot.

### BACKGROUND

As a method for manufacturing a wafer such as a semiconductor wafer, a method has been proposed in which a laser beam with a wavelength that transmits through a single crystal material is applied from a front surface side of an ingot to form a separation layer including a modified region and cracks extending from the modified region inside the ingot, and then a wafer is separated from the ingot with the separation layer as a start point (for example, Japanese Patent Application Laid-Open Publication No. 2016-111143).

This method is a so-called single wafer processing method, which manufactures wafers one by one from an ingot. One surface of the separated wafer is a mirror finish, and the other surface is a separation surface having a modified region.

Therefore, in addition to the original warpage of the material, warpage due to expansion of the modified region also occurs.

Thereafter, the separation surface of the separated wafer is ground to remove the modified region, but there is a problem that it is difficult to transport the wafer if the wafer is warped.

The present disclosure provides a wafer manufacturing method, a laser processing apparatus, and a wafer manufacturing apparatus capable of reducing warpage of a wafer when manufacturing the wafer from an ingot.

### SUMMARY

A first aspect of the present disclosure relates to a wafer manufacturing method for manufacturing a wafer from an ingot includes: holding the ingot; applying a laser beam having a wavelength that transmits through the ingot from a front surface of the ingot and positioning a focal point of the laser beam at a position deeper than the front surface of the ingot to form a modified region, and relatively feeding the ingot and the focal point for processing to form a separation layer including a plurality of the modified regions inside the ingot; separating, from the ingot, a workpiece including the front surface of the ingot as the wafer, with the separation layer as a start point; and grinding a separation surface of the wafer to remove the modified region. In the applying, a depth of the focal point forming the modified region is changed to form the separation surface into a three-dimensional shape rather than a horizontal surface.

A second aspect of the present disclosure relates to a laser processing apparatus including: a holding table configured to hold an ingot; a laser beam emitter configured to apply a laser beam having a wavelength that transmits through the ingot held on the holding table from a front surface of the ingot and position a focal point of the laser beam at a position deeper than the front surface of the ingot to form a modified region, and relatively feed the ingot and the focal point for processing to form a separation layer including a plurality of the modified regions inside the ingot; a moving unit configured to change a relative position between the ingot held on the holding table and a condenser lens of the laser beam emitter; and a controller configured to control the laser processing apparatus. The controller is configured to control the moving unit to change a depth of the focal point forming the modified region inside the ingot.

A third aspect of the present disclosure relates to a wafer manufacturing apparatus for manufacturing a wafer from an ingot: The wafer manufacturing apparatus includes: the laser processing apparatus described above; a separating apparatus configured to separate, from the ingot, a workpiece including the front surface of the ingot as the wafer, with the separation layer as a start point; a first grinding apparatus configured to grind a separation surface of the wafer to make the separation surface of the wafer a horizontal surface; and a second grinding apparatus configured to grind a separation surface of the ingot to make the separation surface of the ingot a horizontal surface.

### BRIEF DESCRIPTION OF DRAWINGS

Exemplary embodiments of the present disclosure will be described in detail based on the following figures, wherein

FIG. 1 is a flowchart of an embodiment of a method for manufacturing a wafer 20;

FIG. 2 is a perspective view illustrating a laser processing apparatus 1;

FIG. 3 is a diagram illustrating a laser beam applying mechanism 8 of the laser processing apparatus 1;

FIG. 4 is a diagram illustrating a state in which a laser beam is applied from a front surface 11a of an ingot 11 by a condenser 84 in a separation layer forming step S11;

FIG. 5 is a diagram illustrating a state in which a separation surface 17 is processed into a triangular shape when viewed from an X-axis direction in the separation layer forming step S11;

FIG. 6 is a diagram illustrating the laser beam applying mechanism 8 according to a modification;

FIG. 7 is a diagram illustrating a state before the wafer 20 is separated from the ingot 11 in a separating step S12;

FIG. 8 is a diagram illustrating a state after the wafer 20 is separated from the ingot 11 in the separating step S12;

FIG. 9 is a diagram illustrating grinding of a front surface 20a (the separation surface 17) of the wafer 20 in a first grinding step S13;

FIG. 10 is a diagram illustrating grinding of the separation surface 17 of the ingot 11 in a second grinding step S14; and

FIG. 11 is a block diagram of a wafer manufacturing apparatus 100.

### DESCRIPTION OF EMBODIMENTS

Hereinafter, an embodiment of the present disclosure will be described with reference to the drawings.

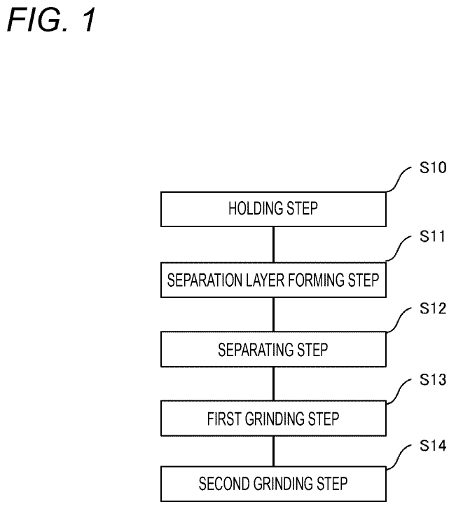

FIG. 1 is a flowchart of an embodiment of a method for manufacturing a wafer 20.

The method for manufacturing the wafer 20 according to the present embodiment includes a holding step S10 of holding an ingot 11, a separation layer forming step S11 of forming a separation layer 15 inside the ingot 11, a separating step S12 of separating, from the ingot 11, a workpiece including a front surface 11a of the ingot 11 as the wafer 20, with the separation layer 15 as a start point, a first grinding step S13 of grinding a separation surface of the wafer 20, and a second grinding step S14 of grinding a separation surface of the ingot 11. The second grinding step S14 is a preprocessing step for manufacturing the next wafer 20.

First, an example of a laser processing apparatus 1 that performs the holding step S10 and the separation layer forming step S11 will be described.

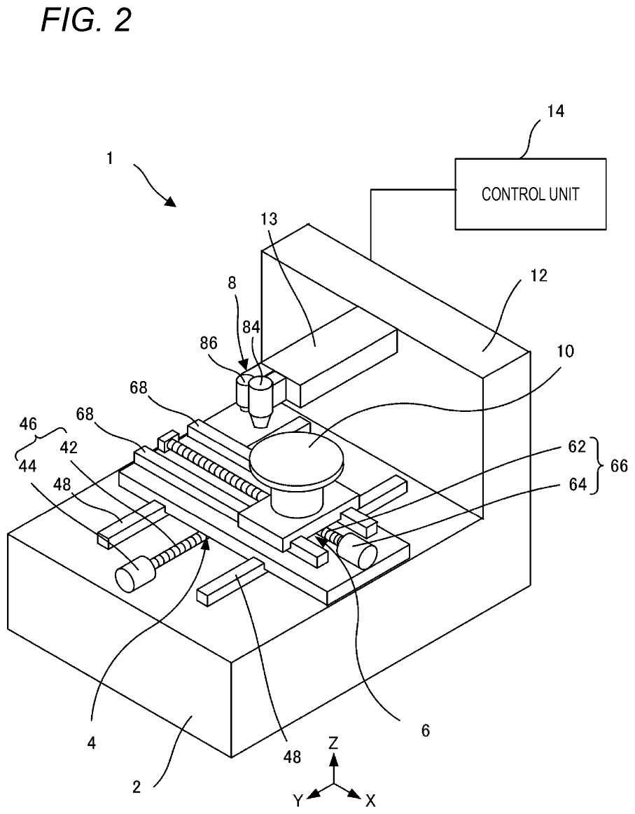

FIG. 2 is a perspective view illustrating the laser processing apparatus 1. In the following description, an X-axis direction is a direction on a horizontal plane. A Y-axis direction is a direction orthogonal to the X-axis direction on the horizontal plane. A Z-axis direction is a direction orthogonal to the X-axis direction and the Y-axis direction.

The laser processing apparatus 1 according to the present embodiment includes a base 2, a first slide block 4 mounted on the base 2 so as to be movable in the Y-axis direction, a second slide block 6 mounted above the first slide block 4 and movable in the X-axis direction, a holding table 10 provided on the second slide block 6, a column 12 erected on the base 2, a laser beam applying mechanism 8 attached to the column 12, and a control unit 14 that controls the laser processing apparatus 1.

The first slide block 4 is implemented to be movable in an indexing direction, that is, in the Y-axis direction along a pair of guide rails 48 by an indexing feeding mechanism 46 including a ball screw 42 and a pulse motor 44.

The second slide block 6 is mounted above the first slide block 4 so as to be movable in the X-axis direction. That is, the second slide block 6 is implemented to be movable in a processing feeding direction, that is, the X-axis direction along a pair of guide rails 68 by a processing feeding mechanism 66 including a ball screw 62 and a pulse motor 64.

The holding table 10 is mounted on the second slide block 6. The holding table 10 is implemented to be movable in the X-axis direction and the Y-axis direction by the processing feeding mechanism 66 and the indexing feeding mechanism 46 and to be rotatable by a motor housed in the second slide block 6.

The column 12 is erected on the base 2, and the laser beam applying mechanism 8 is attached to the column 12.

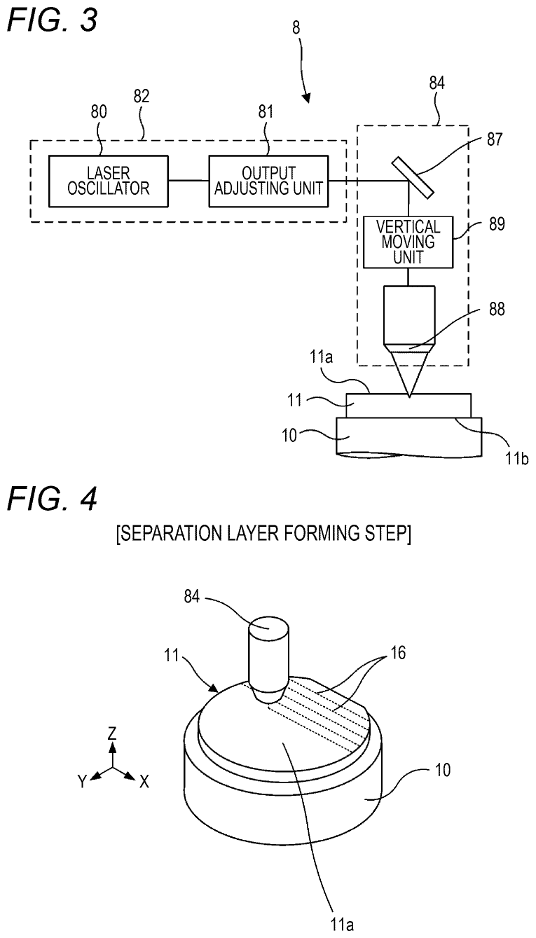

FIG. 3 is a diagram illustrating the laser beam applying mechanism 8 of the laser processing apparatus 1. As illustrated in FIGS. 2 and 3, the laser beam applying mechanism 8 includes a laser beam generating unit 82 housed in a casing 13 and a condenser (laser head) 84 attached to a tip of the casing 13. An imaging unit 86 including a microscope and a camera is attached adjacent to the condenser 84 at the tip of the casing 13.

The laser beam generating unit 82 includes a laser oscillator 80 that oscillates a YAG laser or a YVO4 laser, and an output adjusting unit 81. Although not particularly illustrated, the laser oscillator 80 includes a Brewster window, and the laser beam emitted from the laser oscillator 80 is a linearly polarized laser beam.

A pulsed laser beam adjusted to a predetermined power by the output adjusting unit 81 of the laser beam generating unit 82 is reflected by a mirror 87 of the condenser 84, and is applied with a focal point thereof positioned by a condenser lens 88 to the inside of the ingot 11, which is a workpiece fixed to the holding table 10.

The material for the ingot 11 is not particularly limited, and is, for example, a SiC single crystal ingot or a GaN single crystal ingot. The ingot 11 is not limited to a single crystal ingot and may be a polycrystalline ingot. The ingot 11 has the front surface 11a and a back surface 11b opposite to the front surface 11a. The front surface 11a of the ingot 11 is polished into a mirror finish because the laser beam is applied to the front surface 11a. A thickness of the ingot 11 is, for example, 0.35 mm to 100 mm.

The condenser 84 is provided with a vertical moving unit 89, and is implemented to be able to move the position of the condenser lens 88 in the Z-axis direction. Therefore, the focal point inside the ingot 11 can be moved toward a front surface 11a side by moving the position of the condenser lens 88 upward by the vertical moving unit 89, and the focal point inside the ingot 11 can be moved to a back surface 11b side by moving the position of the condensing lens 88 downward.

The control unit 14 controls each of the components of the laser processing apparatus 1 described above to cause the laser processing apparatus 1 to perform various types of processing on the workpiece. The control unit 14 is a computer including a controller that performs various calculations, a storage unit including a storage medium, and an input and output interface (not illustrated) that controls input and output of data within the control unit 14 or with external devices. The controller includes, for example, a microprocessor such as a central processing unit (CPU). The storage unit includes a memory such as a hard disk drive (HDD), a read only memory (ROM), or a random access memory (RAM). The controller performs various calculations based on a predetermined program stored in the storage unit. The controller outputs, according to a calculation result, various control signals to the components described above via the input and output interface, and controls the laser processing apparatus 1.

Although details will be described later, the control unit 14 controls the vertical moving unit 89 to change the focal point of the laser beam emitted from the laser oscillator 80 inside the ingot 11.

In the laser processing apparatus 1 implemented as described above, in the holding step S10, the ingot 11 is held by the holding table 10 on the second slide block 6.

In the separation layer forming step S11, a laser beam having a wavelength that transmits through the ingot 11 is applied from the front surface 11a of the ingot 11 and the focal point of the laser beam is positioned at a position deeper than the front surface 11a of the ingot 11 to form a modified region, and the ingot 11 and the focal point are relatively fed in the X-axis direction for processing to form the separation layer 15 including a plurality of the modified regions inside the ingot 11.

FIG. 4 is a diagram illustrating a state in which the laser beam is applied from the front surface 11a of the ingot 11 by the condenser 84 in the separation layer forming step S11. In the separation layer forming step S11, the focal point of the laser beam having a transmission wavelength (for example, a wavelength of 1064 nm) with respect to the ingot 11 fixed to the holding table 10 is positioned at a position deeper than the front surface 11a. Then, processing of feeding the ingot 11 for processing so that the focal point moves from one end side to the other end side of the ingot 11 along the X-axis direction to form a modified region along the X-axis direction, subsequently indexing the ingot 11 by a predetermined amount in the Y-axis direction, and then feeding the ingot 11 for processing so that the focal point moves from the other end side to the one end side of the ingot 11 along the X-axis direction to form a modified region along the X-axis direction is repeated. As a result, the modified regions and cracks extending from the modified regions are formed inside the ingot 11, and the separation layer 15 is formed.

Here, in the separation layer forming step S11, the depth of the focal point of the laser beam forming the modified region is changed to form a separation surface 17 between the wafer 20 formed with the separation layer 15 as a start point and the ingot 11 into a three-dimensional shape rather than a horizontal surface. The depth of the focal point of the laser beam is achieved by changing the position of the condenser lens 88 in the Z-axis direction by the vertical moving unit 89.

FIG. 5 is a diagram illustrating a state in which the separation surface 17 is processed into a triangular shape when viewed from the X-axis direction in the separation layer forming step S11. In the separation layer forming step S11, first, the ingot 11 is fed for processing so that the focal point moves from one end side to the other end side of the ingot 11 along the X-axis direction (direction perpendicular to the paper surface) without changing a height position of the focal point in the Z-axis direction, thereby forming a modified region along the X-axis direction. Subsequently, the condenser 84 is moved upward by a predetermined amount along the Z-axis direction when the ingot 11 is fed for indexing by a predetermined amount in the Y-axis direction (right direction of the paper surface). Then, the ingot 11 is fed for processing so that the focal point moves from the other end side to the one end side of the ingot 11 along the X-axis direction without changing the height position of the focal point in the Z-axis direction, thereby forming a modified region along the X-axis direction. This series of processing is repeated until the center in the Y-axis direction is reached. Further, although the same processing is performed from the center in the Y-axis direction, the condenser 84 is moved downward by the predetermined amount along the Z-axis direction when the ingot 11 is fed for indexing by the predetermined amount in the Y-axis direction. As a result, the inside of the ingot 11 is processed such that the separation layer 15 has a triangular shape when viewed from the X-axis direction.

If the modified region extending in the X-axis direction is referred to as a modified line 16, a plurality of the modified lines 16 linearly extending in the X-axis direction between the one end side and the other end side of the ingot 11 are formed in the Y-axis direction inside the ingot 11 as illustrated in FIG. 4. As illustrated in FIG. 5, the depth from the front surface 11a is uniform in the same modified line 16, and the depth from the front surface 11a differs between one modified line 16 and another modified line 16. Therefore, the separation layer 15 formed inside the ingot 11 has a three-dimensional shape rather than a planar shape.

If the separation layer 15 is processed into a horizontal surface, the wafer 20 separated from the ingot 11 in the separating step S12 is warped due to expansion of the modified region in addition to the original warpage of the material for the wafer 20. In contrast, warpage of the wafer 20 can be prevented by forming the separation layer 15 into a three-dimensional shape. In particular, as in the example illustrated in FIG. 5, by applying the laser beam such that the focal point is farther away from the front surface 11a as the focal point is closer to an outer peripheral region of the ingot 11 in the Y-axis direction, the thickness of an outer peripheral region of the wafer 20 increases in the Y-axis direction, and thus the occurrence of warpage in the outer peripheral region of the wafer 20 in which warpage is likely to occur can be prevented.

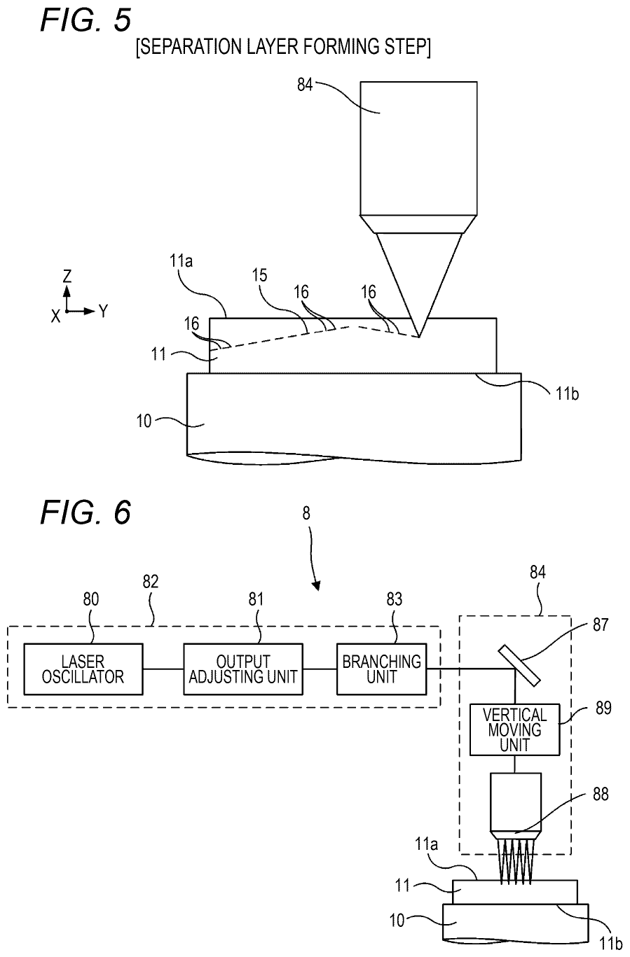

The laser beam applying mechanism 8 of the laser processing apparatus 1 is not limited to the configuration illustrated in FIG. 3, and may have a configuration illustrated in FIG. 6. FIG. 6 is a diagram illustrating the laser beam applying mechanism 8 according to a modification. In the laser beam applying mechanism 8 according to the modification illustrated in FIG. 6, the laser beam generating unit 82 includes a branching unit 83 in addition to the laser oscillator 80 and the output adjusting unit 81. The branching unit 83 branches the laser beam whose output is adjusted by the output adjusting unit 81 into a plurality of laser beams (five laser beams in the present embodiment) at predetermined intervals in a predetermined direction in an XY plane. For example, a plurality of the modified lines 16 can be formed in a single processing feed by branching the leaser beam into the plurality of modified lines 16 in the Y-axis direction in the XY plane.

In this case, since the depth from the front surface 11a differs for each of the plurality of modified lines 16, the separation layer 15 inside the ingot 11 is formed into a triangular shape with a stepped inclined surface when viewed from the X-axis direction.

The three-dimensional shape of the separation layer 15 is not limited thereto, and the depth may change continuously from the front surface 11a in the same modified line 16, and the depth from the front surface 11a may differ between one modified line 16 and another modified line 16. In particular, by applying the laser beam such that the focal point is farther from the front surface 11a as the focal point is closer to the outer peripheral region of the ingot 11 in the X-axis direction and the Y-axis direction, the wafer 20 is formed into a conical shape in which the thickness of the outer peripheral region of the wafer 20 increases in the X-axis direction and the Y-axis direction, and thus the occurrence of warpage in the outer peripheral region of the wafer 20 in which warpage is likely to occur can be prevented. In this case, the modified region is formed along the X-axis direction by feeding the ingot 11 for processing so that the focal point moves from one end side to the other end side of the ingot 11 along the X-axis direction or from the other end side to the one end side while continuously changing the height position of the focal point in the Z-axis direction, which is different from the example illustrated in FIG. 5.

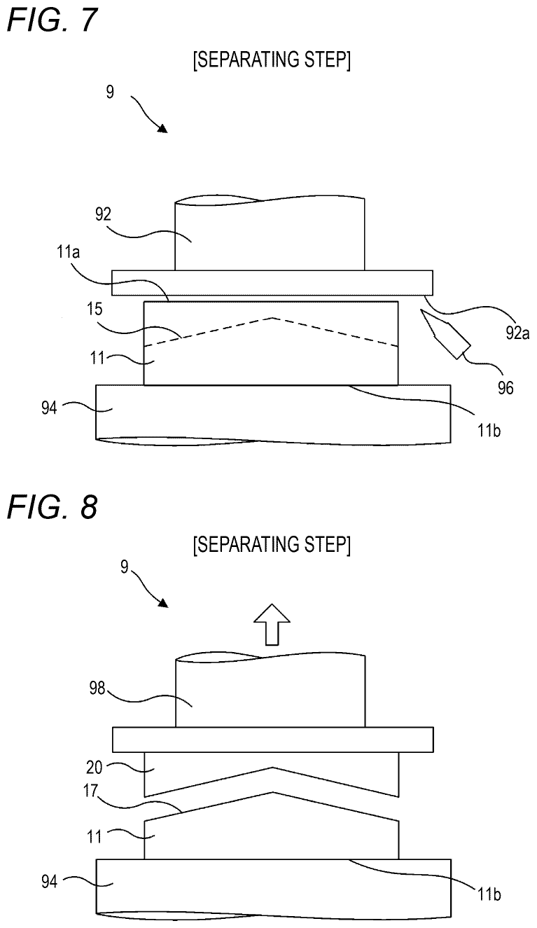

In the separating step S12, a thin plate including the front surface 11a of the ingot 11 is separated as the wafer 20, with the separation layer 15 as a start point. In other words, a part of the ingot 11 is separated from the ingot 11 as the wafer 20. FIG. 7 is a diagram illustrating a state before the wafer 20 is separated from the ingot 11 in the separating step S12, and FIG. 8 is a diagram illustrating a state after the wafer 20 is separated from the ingot 11 in the separating step S12.

As illustrated in FIG. 7, a separating apparatus 9 that performs the separating step S12 includes a separating unit 92 that applies ultrasonic vibration to the front surface 11a of the ingot 11, a holding table 94 that holds the back surface 11b of the ingot 11, and a nozzle 96 that supplies water between a lower surface 92a of the separating unit 92 and the front surface 11a of the ingot 11. In the separating step S12, a slight gap (for example, 0.6 mm) is interposed between the lower surface 92a of the separating unit 92 and the front surface 11a of the ingot 11, and ultrasonic vibration is applied by the separating unit 92 while supplying water from the nozzle 96 to the gap, thereby separating the wafer 20 from the ingot 11 with the separation layer 15 as a start point. Then, as illustrated in FIG. 8, a robot arm 98 adsorbs and moves the wafer 20 upward to separate the wafer 20 from the ingot 11. The separation method is not limited thereto, and the wafer 20 may be separated from the ingot 11 with the separation layer 15 as a start point by physically applying an impact to the holding table 94 by rotating or pressing the separating unit 92 holding the front surface 11a of the ingot 11.

In the separation surface 17 of the wafer 20 separated in the separating step S12, modified regions formed inside the ingot 11 and cracks propagating from the modified regions are exposed. The unevenness of the separation surface 17 due to the modified region or the crack is, for example, 1 μm to 5 μm. Meanwhile, a height difference of the three-dimensional shape of the separation layer 15 is, for example, 10 μm to 20 μm.

Following the separating step S12, in the first grinding step S13, the modified regions formed on the separation surface 17 of the wafer 20, the cracks propagating from the modified regions, and the three-dimensional shape are ground into a horizontal surface (flat surface). Here, in a case in which the separation surface 17 of the wafer 20 is a horizontal surface in an initial grinding stage, there is a risk that the grinding efficiency may deteriorate due to clogging of grindstones, but the clogging of the grindstone can be prevented and the grinding efficiency can be improved by forming the separation surface 17 into a three-dimensional shape.

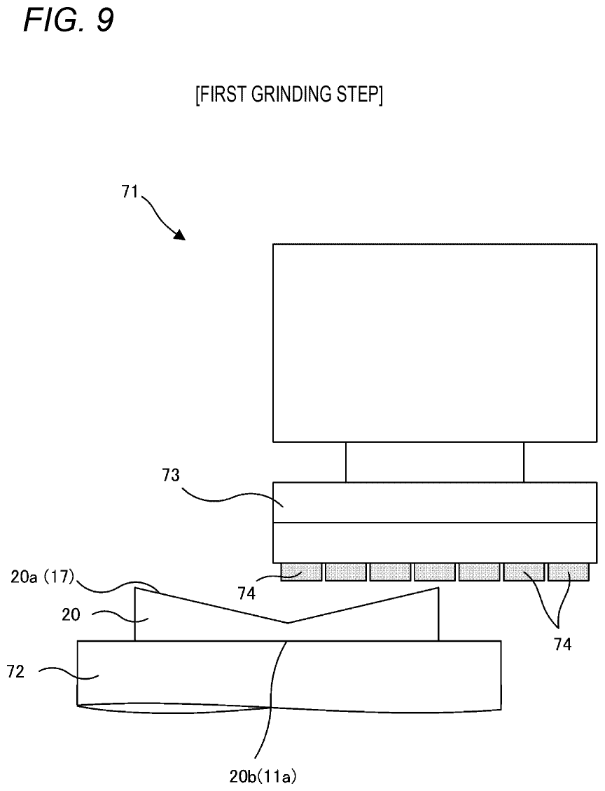

FIG. 9 is a diagram illustrating grinding of a front surface 20a (the separation surface 17) of the wafer 20 in the first grinding step S13. A first grinding apparatus 71 that performs the first grinding step S13 includes, for example, a holding table 72 that holds a back surface 20b of the wafer 20, which is the front surface 11a of the ingot 11 before separation, and a grinding unit 73 that is disposed to face the holding table 72 and is implemented to be vertically movable and rotatable. The first grinding apparatus 71 grinds the separation surface 17, which is the front surface 20a of the wafer 20 held on the holding table 72, with grindstones 74 of the grinding unit 73. In the first grinding step S13, by pressing the grindstones 74 of the grinding unit 73 against the separation surface 17 of the wafer 20 while rotating the grindstones 74, the modified regions and cracks formed on the separation surface 17 of the wafer 20 and the three-dimensional shape are ground to make the separation surface 17 a horizontal surface. As a result, the thin plate-shaped wafer 20 with a uniform thickness is formed.

In the second grinding step S14, the modified regions formed on the separation surface 17 of the ingot 11, the cracks propagating from the modified regions, and the three-dimensional shape are ground into a horizontal surface (flat surface). The second grinding step S14 may be performed in parallel with the first grinding step S13, or may be sequentially performed before and after the first grinding step S13.

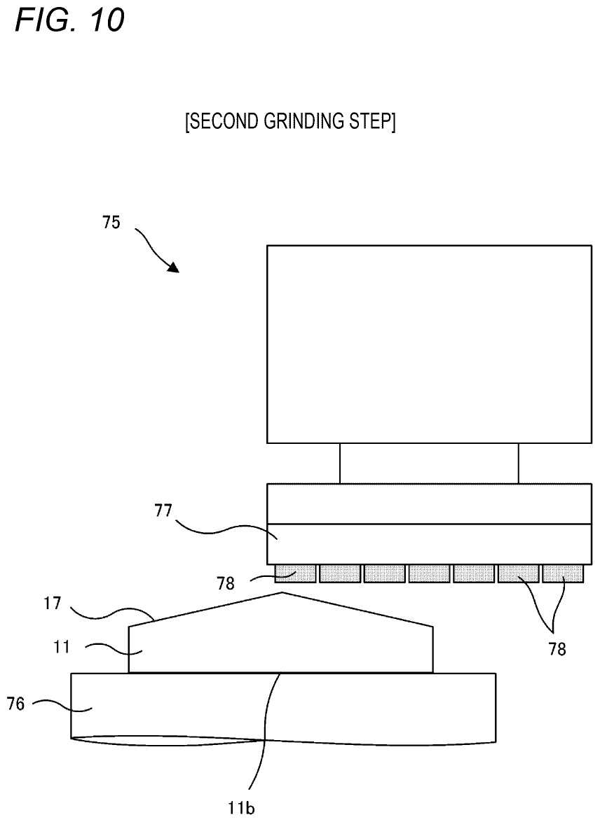

FIG. 10 is a diagram illustrating grinding of the separation surface 17 of the ingot 11 in the second grinding step S14. A second grinding apparatus 75 that performs the second grinding step S14 includes, for example, a holding table 76 that holds the back surface 11b of the ingot 11 before separation, and a grinding unit 77 that is disposed to face the holding table 76 and is implemented to be vertically movable and rotatable. The second grinding apparatus 75 grinds the separation surface 17 of the ingot 11 held on the holding table 76 with grindstones 78 of the grinding unit 77. In the second grinding step S14, by pressing the grindstones 78 of the grinding unit 77 against the separation surface 17 of the ingot 11 while rotating the grindstones 78, the modified regions and cracks formed on the separation surface 17 of the ingot 11 and the three-dimensional shape are ground to make the separation surface 17 a horizontal surface. As a result, the separation surface 17 of the ingot 11 becomes a new horizontal front surface 11a and is used for manufacturing the next wafer 20.

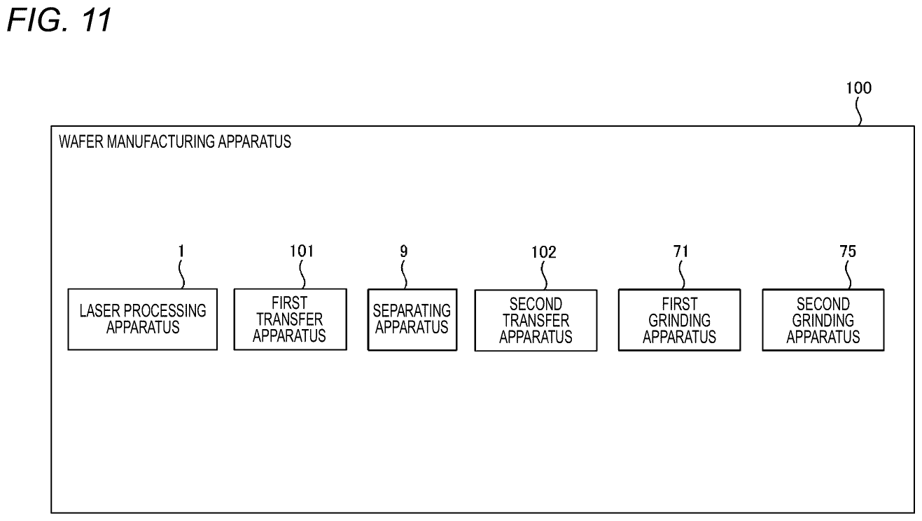

FIG. 11 illustrates an example of a wafer manufacturing apparatus 100 capable of performing the method for manufacturing the wafer 20 according to the present embodiment.

The wafer manufacturing apparatus 100 includes the laser processing apparatus 1, a separating apparatus 9, the first grinding apparatus 71, the second grinding apparatus 75, a first transfer apparatus 101 that transfers the ingot 11 processed by the laser processing apparatus 1 to the separating apparatus 9, and a second transfer apparatus 102 that transfers the wafer 20 separated by the separating apparatus 9 to the first grinding apparatus 71 and transfers the ingot 11 from which the wafer 20 is separated by the separating apparatus 9 to the second grinding apparatus 75. The configurations of the first transfer apparatus 101 and the second transfer apparatus 102 are not particularly limited as long as the first transfer apparatus 101 and the second transfer apparatus 102 are mechanisms capable of appropriately transferring objects to be transferred, and the transferring may be implemented by a conveyor or a robot arm.

Further, in the method for manufacturing the wafer 20 according to the present embodiment, the apparatuses do not need to be integrated into the wafer manufacturing apparatus 100, and the apparatuses may perform processing separately.

Although the embodiment of the present disclosure has been described above with reference to the drawings, it is needless to say that the present disclosure is not limited to the embodiment. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

For example, in the above embodiment, the three-dimensional shape of the separation layer 15 for preventing the warpage of the wafer 20 is exemplified as the shape in which the thickness increases in the outer peripheral region of the wafer 20 in the Y-axis direction and the conical shape in which the thickness increases in the outer peripheral region of the wafer 20 in the X-axis direction and the Y-axis direction, but the three-dimensional shape of the separation layer 15 is not limited thereto, and may be a shape in which the thickness increases in the central region of the wafer 20 in the Y-axis direction or an inverted conical shape in which the thickness increases in the central region of the wafer 20 in the X-axis direction and the Y-axis direction.

When the three-dimensional shape of the separation layer 15 is implemented such that the thickness increases in the central region of the wafer 20 in the Y-axis direction, in the separation layer forming step S11, first, the ingot 11 is fed for processing so that the focal point moves from one end side to the other end side of the ingot 11 along the X-axis direction without changing the height position of the focal point in the Z-axis direction, thereby forming a modified region along the X-axis direction. Subsequently, the condenser 84 is moved downward by a predetermined amount along the Z-axis direction when the ingot 11 is fed for indexing by a predetermined amount in the Y-axis direction. Then, the ingot 11 is fed for processing so that the focal point moves from the other end side to the one end side of the ingot 11 along the X-axis direction without changing the height position of the focal point in the Z-axis direction, thereby forming a modified region along the X-axis direction. This series of processing is repeated until the center in the Y-axis direction is reached. Further, although the same processing is performed from the center in the Y-axis direction, the condenser 84 is moved upward by the predetermined amount along the Z-axis direction when the ingot 11 is fed for indexing by the predetermined amount in the Y-axis direction. As a result, the inside of the ingot 11 is processed such that the separation layer 15 has an inverted triangular shape protruding downward when viewed from the X-axis direction.

Further, when the three-dimensional shape of the separation layer 15 is implemented such that the thickness increases in the central region of the wafer 20 in the X-axis direction and the Y-axis direction, in the separation layer forming step S11, the ingot 11 is fed for processing so that the focal point moves from one end side to the other end side of the ingot 11 or from the other end side to the one end side of the ingot 11 along the X-axis direction while continuously changing the height position of the focal point in the Z-axis direction, thereby forming a modified region along the X-axis direction, which is different from the case in which the thickness increases in the central region of the wafer 20 in the Y-axis direction.

The present specification describes at least the following matters. Corresponding components and the like in the embodiment described above are shown in parentheses, and the present disclosure is not limited thereto.

(1) A wafer manufacturing method for manufacturing a wafer (wafer 20) from an ingot (ingot 11), including:
holding (holding step S10) the ingot;
applying (separation layer forming step S11) a laser beam having a wavelength that transmits through the ingot from a front surface (front surface 11a) of the ingot and positioning a focal point of the laser beam at a position deeper than the front surface of the ingot to form a modified region, and relatively feeding the ingot and the focal point for processing to form a separation layer (separation layer 15) including a plurality of the modified regions inside the ingot;
separating (separating step S12), from the ingot, a workpiece including the front surface of the ingot as the wafer, with the separation layer as a start point; and
grinding (first grinding step S13) a separation surface of the wafer to remove the modified region, in which
in the applying,
a depth of the focal point forming the modified region is changed to form the separation surface into a three-dimensional shape rather than a horizontal surface.

The wafer separated from the ingot is warped due to expansion of the modified region in addition to the original warpage of the workpiece. Therefore, according to (1), warpage of the wafer can be prevented by changing the depth of the focal point of the laser beam to form the separation surface into a three-dimensional shape.

Further, in a case in which the separation surface of the wafer is a horizontal surface in the grinding, there is a risk that the grinding efficiency may deteriorate due to clogging of grindstones, but the clogging of the grindstone can be prevented and the grinding efficiency can be improved by forming the separation surface into a three-dimensional shape.

(2) The wafer manufacturing method according to (1), in which
in the applying,
a plurality of modified lines (modified line 16) each extending linearly in a first direction (X-axis direction) between one end side and the other end side of the ingot are formed inside the ingot in a second direction (Y-axis direction) orthogonal to the first direction, and
the laser beam is applied such that a depth from the front surface is uniform in the same modified line, and the depth from the front surface differs between one modified line and another modified line.

According to (2), since the depth from the front surface is uniform in the same modified line, the control can be prevented from becoming complicated.

(3) The wafer manufacturing method according to (2), in which
in the applying, the laser beam is applied such that the focal point is farther away from the front surface as the focal point is closer to an outer peripheral region of the ingot in the second direction.

According to (3), warpage of the wafer can be prevented by making the focal point deeper as the focal point is closer to the outer peripheral region of the ingot in which warpage of the wafer is likely to occur.

(4) The wafer manufacturing method according to (2), in which
in the applying, the laser beam is applied such that the focal point is farther away from the front surface as the focal point is closer to a central region of the ingot in the second direction.

According to (4), the warpage of the wafer in the outer peripheral region can be prevented by thickening the center of the wafer.

(5) The wafer manufacturing method according to (1), in which
in the applying,
a plurality of modified lines (modified line 16) each extending linearly in a first direction (X-axis direction) between one end side and the other end side of the ingot are formed inside the ingot in a second direction (Y-axis direction) orthogonal to the first direction, and
the laser beam is applied such that a depth from the front surface changes continuously in the same modified line, and the depth from the front surface differs between one modified line and another modified line.

According to (5), a three-dimensional shape can be formed on the separation surface more precisely.

(6) The wafer manufacturing method according to (5), in which
in the applying, the laser beam is applied such that the focal point is farther away from the front surface as the focal point is closer to an outer peripheral region of the ingot in the first direction and the second direction.

According to (6), warpage of the wafer can be prevented by making the focal point deeper as the focal point is closer to the outer peripheral region of the ingot in which warpage of the wafer is likely to occur.

(7) The wafer manufacturing method according to (5), in which
in the applying, the laser beam is applied such that the focal point is farther away from the front surface as the focal point is closer to a central region of the ingot in the first direction and the second direction.

According to (7), the warpage of the wafer in the outer peripheral region can be prevented by thickening the center of the wafer.

(8) The wafer manufacturing method according to any one of (1) to (7), in which
in the grinding, the separation surface of the wafer is ground into a horizontal surface.

According to (8), a wafer having a uniform thickness can be formed.

(9) The wafer manufacturing method according to (1), further including:
grinding (second grinding step S14) a separation surface of the ingot to remove the modified region, in which
in the the grinding of the separation surface of the ingot, the separation surface of the ingot is ground into a horizontal surface.

According to (9), the front surface of the ingot to be applied with the laser beam to manufacture the next wafer can be formed into a horizontal surface, and the separation surface of the next wafer can be formed into a three-dimensional shape with high accuracy.

(10) A laser processing apparatus (laser processing apparatus 1) including:
a holding table (holding table 10) configured to hold an ingot (ingot 11);
a laser beam emitter (laser beam applying mechanism 8) configured to apply a laser beam having a wavelength that transmits through the ingot held on the holding table from a front surface (front surface 11a) of the ingot and position a focal point of the laser beam at a position deeper than the front surface of the ingot to form a modified region, and relatively feed the ingot and the focal point for processing to form a separation layer (separation layer 15) including a plurality of the modified regions inside the ingot;
a moving unit (vertical moving unit 89) configured to change a relative position between the ingot held on the holding table and a condenser lens (condenser lens 88) of the laser beam emitter; and
a controller (control unit 14) configured to control the laser processing apparatus, in which
the controller is configured to control the moving unit to change a depth of the focal point forming the modified region inside the ingot.

According to (10), warpage of the wafer can be prevented by changing the depth of the focal point of the laser beam to form the separation surface into a three-dimensional shape. The clogging of the grindstone can be prevented and the grinding efficiency can be improved by forming the separation surface into a three-dimensional shape.

(11) A wafer manufacturing apparatus (wafer manufacturing apparatus 100) for manufacturing a wafer from an ingot, including:
the laser processing apparatus according to (10);
a separating apparatus (separating apparatus 9) configured to separate, from the ingot, a workpiece including the front surface of the ingot as the wafer, with the separation layer as a start point;
a first grinding apparatus (first grinding apparatus 71) configured to grind a separation surface (separation surface 17) of the wafer to make the separation surface of the wafer a horizontal surface; and
a second grinding apparatus (second grinding apparatus 75) configured to grind a separation surface (separation surface 17) of the ingot to make the separation surface of the ingot a horizontal surface.

According to (11), it is possible to use a single wafer manufacturing apparatus to manufacture wafers with uniform thickness and also form the front surface of the ingot into a horizontal surface for manufacturing the next wafer.

1. A wafer manufacturing method for manufacturing a wafer from an ingot, comprising:
holding the ingot;
applying a laser beam having a wavelength that transmits through the ingot from a front surface of the ingot and positioning a focal point of the laser beam at a position deeper than the front surface of the ingot to form a modified region, and relatively feeding the ingot and the focal point for processing to form a separation layer including a plurality of the modified regions inside the ingot;
separating, from the ingot, a workpiece including the front surface of the ingot as the wafer, with the separation layer as a start point; and
grinding a separation surface of the wafer to remove the modified region, wherein
in the applying,
a depth of the focal point forming the modified region is changed to form the separation surface into a three-dimensional shape rather than a horizontal surface.

2. The wafer manufacturing method according to claim 1, wherein
in the applying,
a plurality of modified lines each extending linearly in a first direction between one end side and the other end side of the ingot are formed inside the ingot in a second direction orthogonal to the first direction, and
the laser beam is applied such that a depth from the front surface is uniform in the same modified line, and the depth from the front surface differs between one modified line and another modified line.

3. The wafer manufacturing method according to claim 2, wherein
in the separation layer forming step, the laser beam is applied such that the focal point is farther away from the front surface as the focal point is closer to an outer peripheral region of the ingot in the second direction.

4. The wafer manufacturing method according to claim 2, wherein
in the separation layer forming step, the laser beam is applied such that the focal point is farther away from the front surface as the focal point is closer to a central region of the ingot in the second direction.

5. The wafer manufacturing method according to claim 1, wherein
in the applying,
a plurality of modified lines each extending linearly in a first direction between one end side and the other end side of the ingot are formed inside the ingot in a second direction orthogonal to the first direction, and
the laser beam is applied such that a depth from the front surface changes continuously in the same modified line, and the depth from the front surface differs between one modified line and another modified line.

6. The wafer manufacturing method according to claim 5, wherein
in the applying, the laser beam is applied such that the focal point is farther away from the front surface as the focal point is closer to an outer peripheral region of the ingot in the first direction and the second direction.

7. The wafer manufacturing method according to claim 5, wherein
in the applying, the laser beam is applied such that the focal point is farther away from the front surface as the focal point is closer to a central region of the ingot in the first direction and the second direction.

8. The wafer manufacturing method according to claim 1, wherein
in the grinding, the separation surface of the wafer is ground into a horizontal surface.

9. The wafer manufacturing method according to claim 1, further comprising:
grinding a separation surface of the ingot to remove the modified region, wherein
in the grinding of the separation surface of the ingot, the separation surface of the ingot is ground into a horizontal surface.

10. A laser processing apparatus comprising:
a holding table configured to hold an ingot;
a laser beam emitter configured to apply a laser beam having a wavelength that transmits through the ingot held on the holding table from a front surface of the ingot and position a focal point of the laser beam at a position deeper than the front surface of the ingot to form a modified region, and relatively feed the ingot and the focal point for processing to form a separation layer including a plurality of the modified regions inside the ingot;
a moving unit configured to change a relative position between the ingot held on the holding table and a condenser lens of the laser beam emitter; and
a controller configured to control the laser processing apparatus, wherein
the controller is configured to control the moving unit to change a depth of the focal point forming the modified region inside the ingot.

11. A wafer manufacturing apparatus for manufacturing a wafer from an ingot, comprising:
the laser processing apparatus according to claim 10;
a separating apparatus configured to separate, from the ingot, a workpiece including the front surface of the ingot as the wafer, with the separation layer as a start point;
a first grinding apparatus configured to grind a separation surface of the wafer to make the separation surface of the wafer a horizontal surface; and
a second grinding apparatus configured to grind a separation surface of the ingot to make the separation surface of the ingot a horizontal surface.
